(19) United States
(12) Patent Application Publication
(10) Pub. No.: US 2026/0247548 A1
(43) Pub. Date: Aug. 20, 2026

(54) ELECTRONIC DEVICE HOUSING AND MANUFACTURING METHOD THEREOF

(71) Applicant: ASUSTEK COMPUTER INC., TAIPEI (TW)

(72) Inventors: Li-Xuan ZHU, TAIPEI (TW); Yu-Jen CHEN, TAIPEI (TW); Yi-Wei LEE, TAIPEI (TW); Yu-Chi WANG, TAIPEI (TW); Chun-Chuan CHUANG, TAIPEI (TW); Ssu-Min WU, TAIPEI (TW); Mu-Chern FONG, TAIPEI (TW); Mao-Jun REN, TAIPEI (TW); Yi-Ting CHEN, TAIPEI (TW); Po-Nien CHEN, TAIPEI (TW); Hsin-Yu TUNG, TAIPEI (TW)

(21) Appl. No.: 19/216,200

(22) Filed: May 22, 2025

(30) Foreign Application Priority Data
Feb. 20, 2025 (TW) 114106252

(51) Int. Cl. H05K 5/02; H05K 9/00

(52) U.S. Cl. CPC H05K 5/0217; H05K 9/0081

(57) ABSTRACT

An electronic device housing is provided. The electronic device housing includes an outer side surface and an inner side surface opposite each other. A plurality of blind holes are formed on the outer side surface. At least a through hole is formed on a bottom surface of each of the blind holes. The through hole penetrates through to the inner side surface. A manufacture method for the electronic device housing is also provided.

### CROSS-REFERENCE TO RELATED APPLICATION

This application claims the priority benefit of Taiwan application serial No. 114106252, filed on Feb. 20, 2025. The entirety of the above-mentioned patent application is hereby incorporated by reference herein and made a part of specification.

### BACKGROUND OF THE INVENTION

### Field of the Invention

The invention relates to an electronic device housing and a manufacturing method thereof and, more particularly, to an electronic device housing with a through hole and a manufacturing method thereof.

### Description of the Related Art

Holes are usually drilled on a housing of a conventional electronic device, such as a speaker, for sound emission or heat dissipation. However, hole areas and shadows on an appearance of the electronic devices affect an appearance of the electronic device.

### BRIEF SUMMARY OF THE INVENTION

An electronic device housing is provided. The electronic device housing includes an outer side surface and an inner side surface opposite each other. A plurality of blind holes are formed on the outer side surface. At least a through hole is formed on a bottom surface of each of the blind holes. The through hole penetrates through to the inner side surface.

A manufacture method for an electronic device housing is also provided. The manufacture method includes: providing a casing, the casing includes an outer side surface and an inner side surface opposite each other; forming a plurality of blind holes on the outer side surface; and forming at least a through hole on a bottom surface of each of the blind holes, respectively, wherein the through hole penetrates through to the inner side surface.

Blind holes are formed on an outer side surface of an electronic device housing in embodiments. At least a through hole penetrating through to an inner side surface are formed on a bottom surface of the blind hole. As a result, a hole area is hidden effectively, and an appearance of the electronic device is better.

### BRIEF DESCRIPTION OF THE DRAWINGS

FIG. 1A and FIG. 1B are a partial top view schematic diagram and a partial cross-sectional view schematic diagram of an electronic device housing according to an embodiment of the invention.

FIG. 2A to FIG. 2G are schematic diagrams showing a manufacture method for an electronic device housing according to an embodiment of the invention.

FIG. 3A to FIG. 3E are schematic diagrams showing a manufacture method for an electronic device housing according to an embodiment of the invention.

FIG. 4 is a partial cross-sectional view schematic diagram of an electronic device housing according to an embodiment of the invention.

### DETAILED DESCRIPTION OF THE EMBODIMENTS

Embodiments of the invention are disclosed in the following drawings, and for more clarity, the details of the disclosure will be described hereinafter. According to the following description and the claims, the advantages and features of this application will be clearer. It should be noted that the drawings are in a very simplified form and all use imprecise proportions, which are only used to conveniently and clearly assist in explaining the purpose of the embodiments.

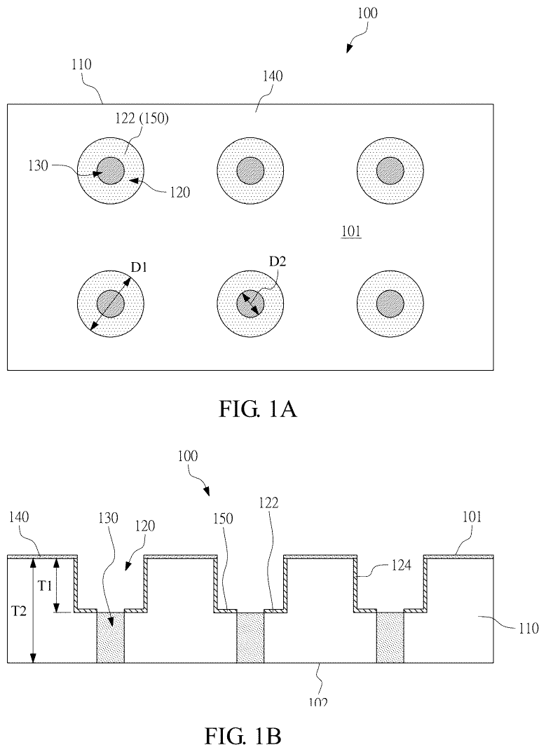

FIG. 1A and FIG. 1B are a partial top view schematic diagram and a partial cross-sectional view schematic diagram of an electronic device housing 100 according to an embodiment of the invention. The electronic device housing 100 is a housing of a notebook, the housing of a speaker, or the housing of other electronic devices with heat dissipation or sound-emitting functions.

As shown in FIG. 1A and FIG. 1B, a casing 110 of the electronic device housing 100 includes an outer side surface 101 and an inner side surface 102 opposite each other. The outer side surface 101 is an appearance surface of the casing 110 of the electronic device housing 100. In embodiments, the casing 110 is made of metal materials (such as an aluminum alloy, an aluminum-magnesium alloy), plastic materials, or composite materials, which is not limited herein.

A plurality of blind holes 120 are formed on the outer side surface 101. At least a through hole 130 (one through hole 130 is shown as an example) penetrating through to the inner side surface 102 is formed on a bottom surface 122 of each of the blind holes 120. In an embodiment, the blind holes 120 are arranged in an array on the outer side surface 101.

In the embodiment, an opening shape of the blind hole 120 is the same as that of the through hole 130. In the embodiment, the opening shape is circle, and a diameter D1 of the blind hole 120 is larger than the diameter D2 of the through hole 130. In the embodiment, the through hole 130 is located in the center of the bottom surface 122 of each of the blind holes 120, which is not limited herein. The shapes of the blind holes 120 are various according practical requirements, such as squares, triangles, hexagons, strips, which not limited to circles. Moreover, in an embodiment, the opening shape of the blind hole 120 is different from that of the through hole 130. In an embodiment, a plurality of through holes 130 are formed on the bottom surface 122 of one blind hole 120, and the through holes 130 are symmetrically arranged on the bottom surface 122 of the blind hole 120.

In an embodiment, the aperture diameter D1 of the blind hole 120 is 1.4 to 4 times the aperture diameter D2 of the through hole 130. In an embodiment, the depth T1 of the blind hole 120 is ¼ to ¾ times the thickness T2 of the housing 100, which is not limited herein.

In an embodiment, as shown in FIG. 1A and FIG. 1B, an appearance layer 140 covers the outer side surface 101 around the opening of the blind hole 120. A shielding layer 150 covers inside the blind hole 120. The shielding layer 150 extends from the bottom surface 122 of the blind hole 120 to the side wall 124 of the blind hole 120. The color of the shielding layer 150 is darker than that of the appearance layer 140. The shielding layer 150 helps hide the through hole 130 (that is, the hole area) on the bottom surface 122 of the blind holes 120 effectively. Consequently, the appearance of the electronic device is better.

In an embodiment, different colored paints are used to form the appearance layer 140 and the shielding layer 150, respectively. In an embodiment, the appearance layer 140 is a first color paint layer, and the shielding layer 150 is a second color paint layer. The color of the second color paint layer is darker than that of the first color paint layer.

In an embodiment, a paint with a higher grayscale is selected to make the shielding layer 150, and a paint with a lower grayscale is used to make the appearance layer 140, and then the shielding layer 150 presents a darker color. For example, according to a definition of the CIELAB color space, the L-value of the color of the shielding layer 150 is set to be lower than 31, the A-value and B-value of the color of the shielding layer 150 are also set to be lower than 31, and the L-value of the color of the appearance layer 140 is set to be higher than that of the shielding layer 150.

In an embodiment, a paint with lower light reflectance is selected to make the shielding layer 150, and a paint with higher light reflectance is selected to make the appearance layer 140 to help hide the through holes 130 (that is, the hole area) located on the bottom surfaces 122 of the blind holes 120.

In the above embodiment, paints are used to form the shielding layer 150 and the appearance layer 140, which is not limited herein. In an embodiment, a surface treatment method, such as an anodizing treatment, is used to form the shielding layer 150 and the appearance layer 140 on the housing 100. In an embodiment, the anodizing treatment is used in combination with dyes to color the anodized layer. In an embodiment, the appearance layer 140 is a first anodizing treatment layer, and the shielding layer 150 is a second anodizing treatment layer. The color of the second anodizing treatment layer is darker than that of the first anodizing treatment layer.

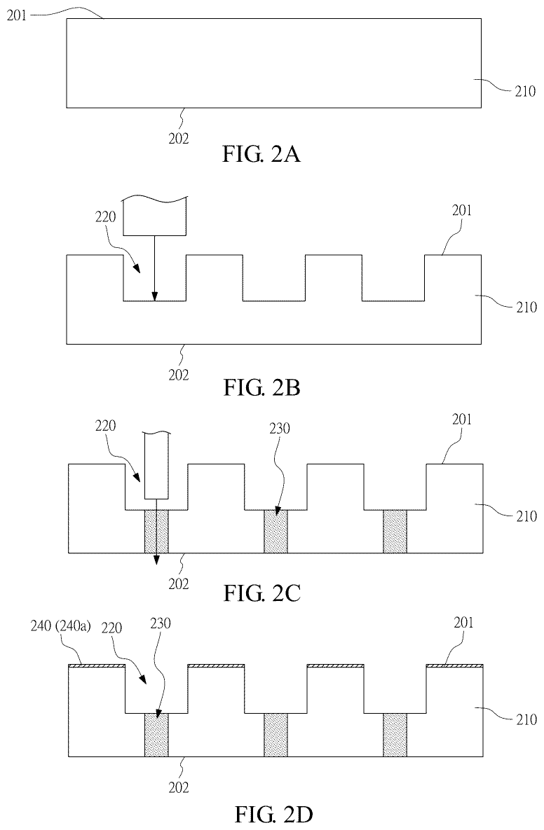

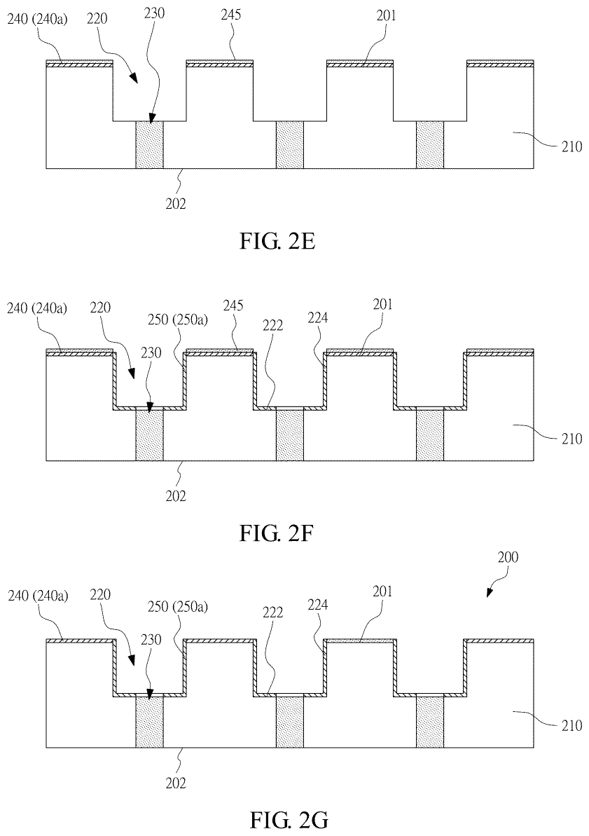

FIG. 2A to FIG. 2G are schematic diagrams showing a manufacture method for an electronic device housing 200 according to an embodiment of the invention. In the embodiment, colored paints are used to color an outer side surface 201 of a casing 210 and a bottom surface 222 of blind holes 220.

First, as shown in FIG. 2A, the casing 210 is provided. The casing 210 includes the outer side surface 201 and an inner side surface 202 opposite each other. The outer side surface 201 is the appearance surface of the casing 210. In embodiments, the casing 210 is made of metallic materials (such as an aluminum alloy, an aluminum-magnesium alloy), plastic materials, or composite materials, which is not limited herein.

Next, as shown in FIG. 2B, a plurality of blind holes 220 are formed on the outer side surface 201. In an embodiment, a mechanical processing method, such as drilling, is used to form the blind holes 220 on the outer side surface 201. In an embodiment, the blind holes 220 are arranged in an array on the outer side surface 201.

Next, as shown in FIG. 2C, at least a through hole 230 (one is shown as an example) penetrating through to the inner side surface 202 is formed on the bottom surface 222 of the blind holes 220. In an embodiment, a mechanical processing method, such as drilling, is used to form at least a through hole 230 on the bottom surface 222 of each of the blind holes 220.

In an embodiment, the blind holes 220 or the through holes 230 are formed by etching with a potion, which is not limited herein.

In the embodiment, one through hole 230 is formed in the center of the bottom surface 222 of each of the blind holes 220, which is not limited herein. In an embodiment, the shape of the blind hole 220 is different from that of the through hole 230 according practical requirements, and a plurality of through holes 230 are formed on the bottom surface 222 of each of the blind holes 220, respectively.

Next, as shown in FIG. 2D, the outer side surface 201 is colored. In an embodiment, the first color paint layer 240a (that is, the appearance layer 240) is formed on the outer side surface 201 via spray painting or other processing methods, which is not limited herein.

Next, as shown in FIG. 2E, a protection layer 245 is formed to cover the outer side surface 201. In the embodiment, the protection layer 245 is a removable coating layer or an adhesive tape.

Next, as shown in FIG. 2F, the inside of the blind hole 220 is colored to make the color of the bottom surface 222 of the blind hole 220 darker than that of the outer side surface 201. In an embodiment, a processing method, such as spray painting, is used to coat a color paint material on the casing 210 (including the inside of the blind hole 220). Since the outer side surface 201 of the casing 210 is covered with the protection layer 245, the outer side surface 201 maintains an original color (that is, the color of the first color paint layer 240a). The color paint material extending into the blind hole 220 is the second color paint layer 250a (that is, the shielding layer 250). The second color paint layer 250b not only covers the bottom surface 222 of the blind hole 220, but also covers the side wall 224 of the blind hole 220. The color of the second color paint layer 250a is darker than that of the first color paint layer 240a.

Next, as shown in FIG. 2G, the protection layer 245 covering the outer side surface 201 is removed to expose the first color paint layer 240a (that is, the appearance layer 240).

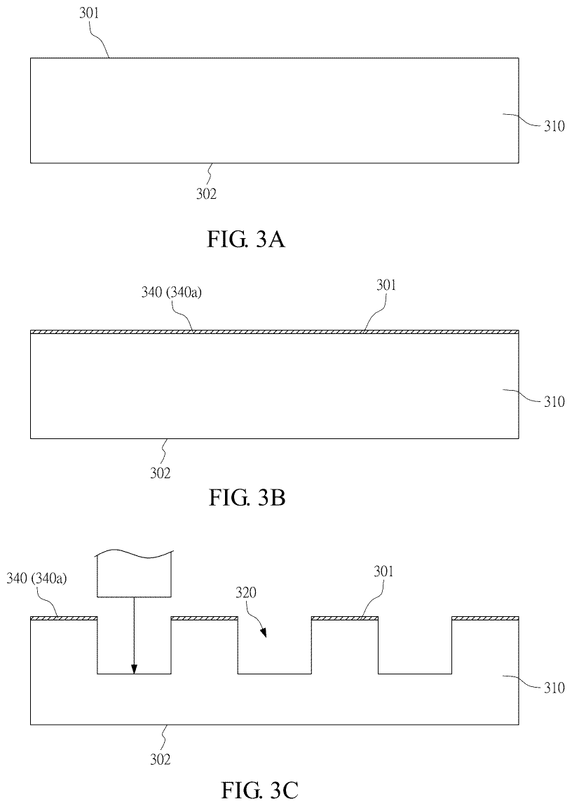

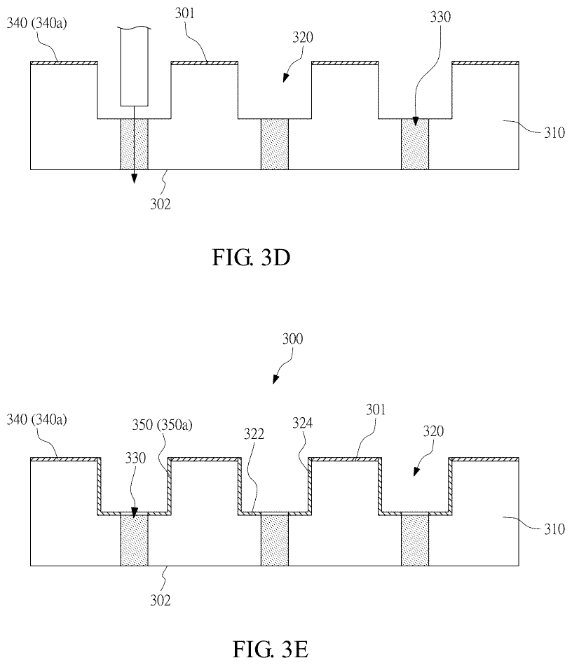

FIG. 3A to FIG. 3E are schematic diagrams showing a manufacture method 300 for an electronic device housing according to an embodiment of the invention. In the embodiment, the anodizing treatment is used to color an outer side surface 301 of a casing 310 and a bottom surface 322 of blind holes 320.

As shown in FIG. 3A, first, the casing 310 is provided. The casing 310 includes the outer side surface 301 and an inner side surface 302 opposite each other. The outer side surface 301 is the appearance surface of the casing 310. In embodiments, the casing 310 is made of a metal material (such as an aluminum alloy, an aluminum-magnesium alloy), plastic materials or composite materials.

Next, as shown in FIG. 3B, the first anodizing treatment is performed on the casing 310 to form a first anodizing treatment layer 340a (that is, the appearance layer 340) on the outer side surface 301.

Next, as shown in FIG. 3C, a plurality of blind holes 320 are formed on the outer side surface 301. The blind holes 320 penetrate the first anodizing treatment layer 340a to expose a base material of the casing 310.

Next, as shown in FIG. 3D, at least a through hole 330 (one is shown in figures) penetrating through to the inner side surface 302 is formed on the bottom surface 322 of each of the blind holes 320.

Next, as shown in FIG. 3E, the second anodizing treatment is performed on the casing 310 to form a second anodizing treatment layer 350a (that is, the shielding layer 350) on the inner side surface 302 of the blind hole 320. The second anodizing treatment layer 350a both covers on the bottom surface 322 of the blind hole 320 and covers the side wall 324 of the blind hole 320. The color of the second anodizing treatment layer 350a is darker than that of the first anodizing treatment layer 340a.

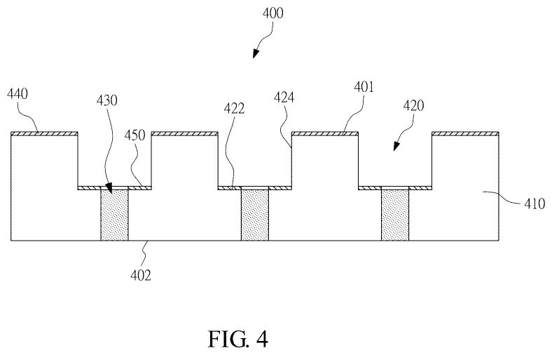

FIG. 4 is a partial cross-sectional view schematic diagram of an electronic device housing 400 according to an embodiment of the invention.

As shown in FIG. 4, a casing 410 of the electronic device housing 400 includes an outer side surface 401 and an inner side surface 402 opposite each other. A plurality of blind holes 420 are formed on the outer side surface 401. At least a through hole 430 (one is shown in figures) penetrating through to the inner side surface 402 is formed on a bottom surface 422 of each of the blind hole 420.

In the embodiment shown in FIG. 1B, the shielding layer 150 is fully cover the inner side surface 102 of the blind hole 120. That is, the shielding layer 150 extends from the bottom surface 122 of the blind hole 120 to the side wall 124 of the blind hole 120. In contrast, the shielding layer 450 in this embodiment covers the bottom surface 422 of the blind hole 420 but not cover the side wall 424 of the blind hole 420.

Other structures of the electronic device housing 400 in this embodiment, such as an appearance layer 440, are similar to corresponding structures of the electronic device housing 100 in the embodiment in FIG. 1B, which is not described herein for a concise purpose.

Blind holes are formed on an outer side surface of an electronic device housing in embodiments. At least a through hole penetrating through to an inner side surface are formed on a bottom surface of the blind hole. As a result, a hole area is hidden effectively, and an appearance of the electronic device is better.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. An electronic device housing, comprises an outer side surface and an inner side surface opposite each other, a plurality of blind holes are formed on the outer side surface, at least a through hole is formed on a bottom surface of each of the blind holes, and the through hole penetrates through to the inner side surface.

2. The electronic device housing according to claim 1, wherein the bottom surface is covered with a shielding layer.

3. The electronic device housing according to claim 2, wherein the shielding layer is a first color paint layer or a first anodizing treatment layer.

4. The electronic device housing according to claim 2, wherein the outer side surface around an opening of the blind hole is cover with an appearance layer.

5. The electronic device housing according to claim 4, wherein the appearance layer is a second color paint layer or a second anodizing treatment layer.

6. The electronic device housing according to claim 4, wherein a grayscale of the shielding layer is higher than that of the appearance layer.

7. The electronic device housing according to claim 4, wherein a light reflectance of the shielding layer is lower than that of the appearance layer.

8. The electronic device housing according to claim 2, wherein the shielding layer extends from the bottom surface to cover a side surface of the blind hole.

9. The electronic device housing according to claim 1, wherein a diameter of the blind hole is larger than that of the through hole.

10. The electronic device housing according to claim 1, wherein a depth of the blind hole ranges from ¼ to ¾ of a thickness the housing.

11. The electronic device housing according to claim 1, wherein opening shape of the blind hole is the same as that of the through hole.

12. A manufacture method for an electronic device housing, comprising:
providing a casing, wherein the casing includes an outer side surface and an inner side surface opposite each other;
forming a plurality of blind holes on the outer side surface; and
forming at least a through hole on a bottom surface of each of the blind holes, respectively, wherein the through hole penetrates through to the inner side surface.
